(19) United States
(12) Patent Application Publication
(10) Pub. No.: US 2015/0228505 A1
(43) Pub. Date: Aug. 13, 2015

(54) MOULDING METHOD FOR PRODUCING AN ELECTRONIC HOUSING

(71) Applicant: GEMALTO SA, Meudon (FR)

(72) Inventors: Stéphane Ottobon, La Ciotat (FR); Lucile Dossetto, La Ciotat (FR); Laurent Audouard, La Ciotat (FR); Sébastien Guijarro, La Ciotat (FR)

(73) Assignee: GEMALTO SA, Meudon (FR)

(21) Appl. No.: 14/424,124

(22) PCT Filed: Sep. 17, 2013
(86) PCT No.: PCT/EP2013/069297

§ 371 Date: Feb. 26, 2015

(30) Foreign Application Priority Data
Sep. 18, 2012 (EP) 12306128.5

(51) Int. Cl. H01L 21/48

(52) U.S. Cl. CPC H01L 21/4803

(57) ABSTRACT

The invention concerns a method for producing a smart card or telecommunication module electronic housing, comprising an electronic chip in the housing, a face comprising at least one set of conductive metal platings, said method comprising the following steps: providing or producing at least one set of metal platings comprising conductive circuit pads or tracks, on one side of a substrate, transferring and connecting a chip to each set of platings, overmoulding each chip with the set of metal platings of same on the substrate with a moulding material in order to produce at least one housing, separating the housing from the substrate thereof, wherein the side of the substrate in contact with the metal platings comprises an adhesive or has low adhesiveness and in that the overmoulding is carried out at the final dimensions of the housing. The invention also concerns a moulding apparatus and the housing obtained.

### FIELD OF THE INVENTION

The invention concerns a moulding method for producing an electronic housing comprising a chip and/or an electronic component as well as the housing obtained.

The invention also concerns the production of telecommunication modules for machines, in particular of the M2M type, which may have different shape factors.

Such housings can be found for example in the form of modules for chip cards, with diverse shape factors such as those of small electronic objects with micro-SD (Secure Digital), Micro-SIM (Subscriber Identity Module) or Plug-in SIM, Mini UICC (Universal Integrated Circuit Card) formats. An entire range of housings can also be found for the surface mounting of components (CMS or SMD) as well as housings of the BGA (Ball Grid Array) type comprising connection balls. These housings comprise a supply and/or communication interface in particular with electrical or antenna-type contacts.

The invention concerns more particularly, but not limitatively, the production of secure portable electronic objects such as chip cards or modules that find in particular their applications in health, banking, telecommunications or identity checking or physical and/or logic access control.

### PRIOR ART

The known techniques for manufacturing such objects require a method that is sometimes slow, complex and not very adaptable, among which the following steps are mainly found:
Definition of a dedicated printed circuit roll;
Mechanical cutting of said printed circuit or chemical etching for defining a contact form;
Cutting in a dielectric in order to create connection wells;
Lamination of the dielectric on the printed circuit;
Metallisation of contact pads;
Bonding of one or more chips of variable thicknesses;
Wiring by means of wires for interconnecting said chips and connecting the contact points;
Coating with a protective resin, etc.

At the present time, the housings are generally assembled on the same substrate using a printed-circuit substrate (PCB or lead frame) on which several housings are bonded, welded and overmoulded. Separating these moulded housings requires a step of separation by cutting by means of any type of cutting method (mechanical sawing, punching, laser, water jet). This step gives rise to a major part of the production cost.

Moreover, since the thickness or overall size of current housings are constantly decreasing to allow a greater integration in portable appliances and telephones, it is necessary for this purpose to provide a more suitable method for manufacturing or designing the housings.

### TECHNICAL PROBLEM

The objective of the invention is to respond to the aforementioned drawbacks of manufacturing cost and/or size.

### SUMMARY OF THE INVENTION

The principle of the invention is based on the moulding of a special substrate, described below, in which the contacts or circuit tracks or supply and/or communication interfaces will be detached from a low-adhesion substrate (or a substrate wherein the adhesion may be altered subsequently to allow separation of the substrate from a block) and be transferred in a moulding.

To this end, the subject matter of the invention is a method for producing an electronic housing comprising an electronic chip, one face of which comprises at least some conductive metallisations, said method comprising the following steps:
supply or production of at least one set of metallisations comprising conductive circuit tracks or pads, on one side of the support;
transfer and connection of a chip to each set of metallisations,
overmoulding of each chip on its support,
separation of the housing from its support.

The method is characterised in that the support comprises an adhesive or has adhesiveness that is lower by nature or alterable and in that the moulding is effected to the final dimension of the housing.

Another subject matter of the invention is moulding equipment according to claims 7 and 8 as well as the electronic housing obtained according to claim 9.

### BRIEF DESCRIPTION OF THE FIGURES

FIGS. 1 to 7 illustrate a method for producing an electronic housing according to one embodiment of the invention;

FIGS. 8 to 12 illustration a production installation and method according to a second embodiment of the invention;

FIG. 13 illustrates various views of objects/housings according to one of the embodiments of the invention.

### DESCRIPTION

The method of the invention according to the first embodiment comprises a step of supplying or producing at least one set of metallisations comprising conductive-circuit pads or tracks producing a communication and/or supply interface, in particular with electrical and/or radio-frequency antenna contacts, on an adhesive support or one with low adhesiveness.

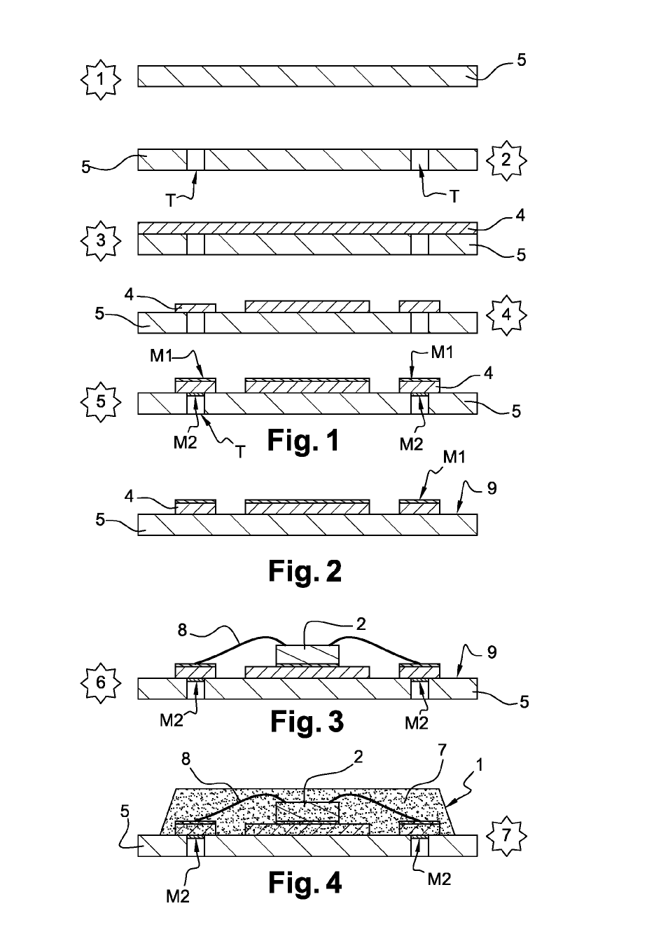

In the example in FIG. 1 (operations 1 to 5), a step of producing at least one set of metallisations 4 comprising contacts on a detachable/separable substrate 5 is illustrated. The substrate or support is a dielectric film chosen for its low-adhesion properties so that the moulding is easily detached, such as for example a PET (polyethylene terephthalate), a PEN (polyethylene naphthalate) or an inexpensive substrate of the paper type.

In the case of an antenna, this can be produced flat in spiral form. The description is given preferentially for metallisation with electric contacts but the invention can also apply to other electrically conductive elements such as tracks or antennas.

Throughout the description, the interface with contacts 4 may be replaced by a radio-frequency interface with antenna.

Preferably, the support (5) is determined with a plurality of regions intended each to receive a set of metallisations and a housing.

In the case where the surface metallisations are produced by means of a method involving current-feed tracks, care will be taken that these tracks are few in number and have a configuration facilitating cutting/separation when the housings are separated from the low-adhesiveness support, for example having a kind of contraction or scoring or reduction in cross-section at the point where they are to be cut.

Hereinafter, it will be seen that the adhesive may be, according to the variants of the method, an adhesive with low adhesiveness through its nature or degradable under heat or degradable under UV (ultraviolet) so that each set of metallisations, in particular made from copper, is easily detached. The low-adhesiveness values so that the metallisations and the moulding can be detached from the support may typically be between 0.5 and 5 newtons/cm under the 90 degree peeling resistance test. The peeling rate may for example be 30 cm/minute or more.
At operations 1 and 2, the adhesive (or low-adhesiveness) dielectric is pierced in particular by punching;
At operation 3, a temporary fixing is carried out, in particular by lamination of a conductive sheet, in particular made from copper, on the dielectric support;
At operation 4, chemical etching of the conductive sheet is carried out in order to produce the form of the external contacts of the housing or circuit required;
At step 5, a surface treatment M1, M2 of the copper parts, for example made from NI/Pd/Au, can preferably be carried out.

This surface treatment in particular of metallisation (anti-oxidation, passivation) M1 and/or M2 can be done on the two faces of the copper, also through each hole T in the support, so that the external contacts thus appear substantially on the external surface of the housing (to within the thickness of the treatment layer or the layer of adhesive on the support referred to below).

If the substrate is only slightly adhesive as described below, the surface treatment (treatment metallisation) only slightly goes beyond the level of the overmoulding surface.

If the substrate comprises or not a layer of glue as described below in a variant, the layer M2 of the surface treatment comprising a treatment metallisation in the hole in the support (to be distinguished from the metallisation 4 of the support) may have a level higher than the surface level of the face 3 of the overmoulding.

According to any one of the embodiments, an adhesion of the metallisation that is greater in contact with the moulding resin can be provided. The adhesion may be obtained by various known methods: for example, by increasing the roughness of the copper of the circuit, by increasing the surface roughness (the additional metallisation of the Ni/Pd/Au (nickel, palladium, gold) type will follow this roughness), by plasma before moulding, by points anchoring the moulding in conductive parts of the metallisations.

According to a variant embodiment, the above substrate may be non-punched, as illustrated in FIG. 2; in this case, the external contacts 4 may remain made from copper (optionally protected from oxidation by organic passivation or other prior or subsequent surface treatment).

According to another variant embodiment, the above substrate may be punched, as illustrated in FIG. 1, with a number of holes greater than those necessary for being metallised, in order to facilitate the subsequent separation of the low-adhesiveness support from the housing, the facing surface being in fact smaller.

Alternatively, the contact pads may be perforated in order to limit the adhesion and to save on the metallisations and/or to allow electromagnetic permeability in the case where the object also comprises a radio-frequency antenna, for example etched on the support.

Where applicable, an antenna (not shown) is produced, for example at the same level as the conductive contacts or tracks, in particular at the periphery and/or at the centre of the contact pads 4 in a central region 40. The antenna, which may be an antenna that is in particular active or passive (relay antenna), may optionally be printed on the main surface moulding material in front of or behind the moulding material.

According to an alternative to the preferred etching operation in the invention, it is possible to provide for fixing or printing an electrically conductive grill (in particular by a jet of conductive material) on the support in order to form electrical contacts and/or tracks and/or at least one antenna.
At operation 6 (FIG. 3), an electronic chip 2 with integrated circuits is transferred onto the support or the conductive elements (pads, tracks, antenna turns);
At the optional operation 6b is (not shown), before or after the fixing of the chip, in particular by adhesive bonding, it is possible to use an optional cleaning plasma for improving the adhesion of the moulding resin on the metallised contacts;
At operation 7 (FIG. 4), the moulding is carried out to the final dimension of the housing 1 with an insulating overmoulding material 7;
At operation 8 (FIGS. 5, 6, 7), there is a separation from the housing 1 from its contacts (or overmoulding material 7), or from the substrate (different variants are disclosed below).

Preferably, the support (5) is determined with a plurality of housing-reception regions in order to produce a plurality of housings in series.

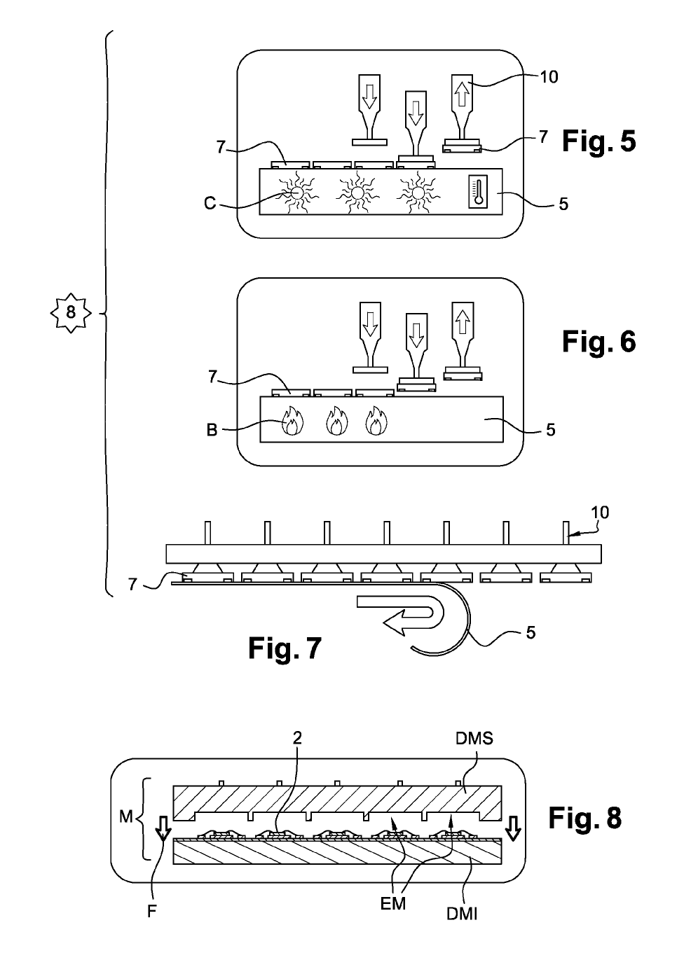

It is then possible to proceed, on such a support, with a gripping of the housings, in particular by suckers 10 (FIGS. 5, 6) disposed on robotic movable grippers 10 after having heated “C” the support, in particular by means of infrared lamps, in order to degrade the adhesion of the adhesive temporarily holding the housings on the support 5 and thus to enable the housing 1 to be separated from its set of metallisations (contacts, tracks), with respect to the support 5. The adhesive may be a thermoplastic or thermo-fusible adhesive.

In an alternative (FIG. 6), the support can be destroyed, in particular by burning “B” (in the case in particular of a paper substrate 25). It is also possible to separate the individual housings by peeling the substrate 5 (FIG. 7), the housings being held on nozzles 10 by suction.
FIGS. 8 to 12 describe a manufacturing installation and method according to a second embodiment of the invention.

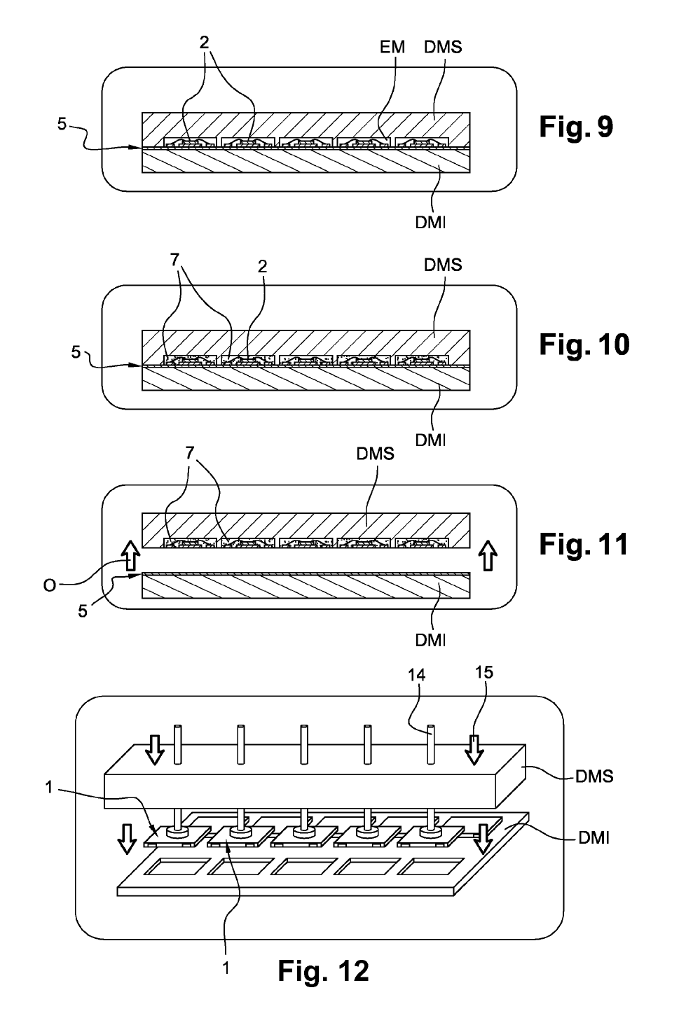

Use is made of a mould M (FIG. 8), comprising a first bottom part DMI to support the substrate or support 5 and a corresponding second top part DMS comprising a plurality of moulding cavities (EM) to the dimensions and shapes corresponding to the objects/housings to be obtained.
In FIG. 9, the mould DMS, DMI is closed again following the movement (F) of the top part DMS against the bottom part DMI and against the substrate 5. A plurality of moulding spaces (EM) corresponding to the moulding cavities CM are defined above the substrate and the plurality of electronic chips.
In FIG. 10, material is injected into the moulding spaces in order to overmould each electronic chip and to form each housing. The mould comprises, in a known manner (not shown), one or more points for injecting material into each moulding cavity (EM), for example on the walls of each cavity corresponding to an edge of the objects or rear face (opposite to the face 3 carrying the contacts 4);
In FIG. 11, the top part DMS of the mould moves away (O) from the bottom part in order to open the mould, the support or substrate 5 being held on the bottom part DMI of the mould in particular by suction. Any other holding or traction means, in particular mechanical, exerting a separation force on the support 5 with respect to the housings when the mould is open can be envisaged.

The moulded housings can be cavities (EM) or compartments of the mould (FIG. 11) when the top part of the mould is raised (0); ejectors 14 slide (15) in the top part of the mould DMS above the housings and against their rear face, through each moulding cavity (EM), in order to extract the housings from their cavity so as to fall into a recovery bowl or directly into a dedicated tray having recesses for receiving the housings (FIG. 12).

The delamination of the housings on the substrate is facilitated since the moulding takes place at high temperature (approximately 180° C.) and the adhesive has been chosen so as to degrade at approximately this temperature. Ejectors 14 sliding on the top part DMS of the mould can hold this substrate on the bottom part of the mould DMI.

It is possible to proceed as follows. The support carrying the metallisations and at least one connected chip is introduced in advance into a mould and then, after overmoulding, the support 5 can be withdrawn from the metallisations or be destroyed. The support can also be disconnected from the metallisations while being altered in particular by the addition of heat during the overmoulding in a mould. The adhesive can therefore preferably be altered fairly quickly (for example in less than one minute or the injection time of a few seconds) to enable the support to be removed just after overmoulding.

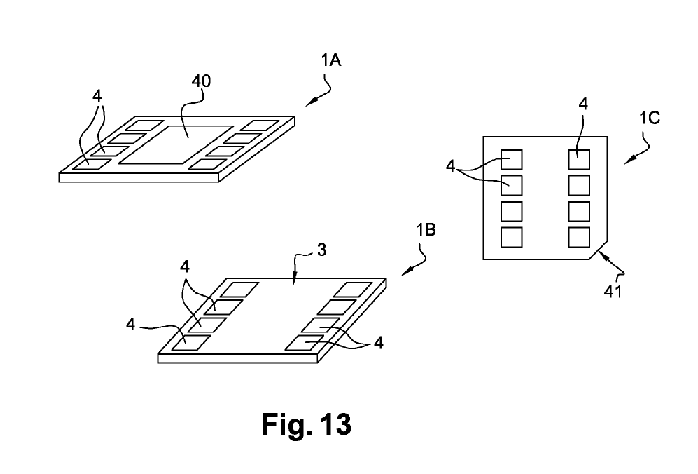

In FIG. 13, the objects/housings here are in the form of mini-cards 1A, 1B, 1C with electrical contacts 4 showing on the principal surface. The moulding material or resin 7 constituting the insulated body of the card or object comprises a face 3 that can be situated at the same level as the contact pads 4. In other words, the various metallisations are spaced apart by insulating moulding material showing at the same surface level (or substantially at the same level as explained above) as that of the insulation. The metallisations are substantially at the same level as the moulding material on the face 3. The pads are preferably intended to directly connect a connector for a chip card reader or communication terminal such as a telephone, a personal assistant, a computer, a camera or a communication apparatus able to receive/connect a communication module of the SIM or M2M type in a fixed or removable manner.

Where applicable, the cards or mini cards or SIM or M2M communication module can be bonded/fixed to the reader with conductive material or resin.

Where applicable, according to the surface treatment variants, there may be a slight difference of level between the contacts or interface and the overmoulding material.

According to the deposited thickness of the treatment metallisation such as for example Ni/Pd/Au, the conductive contact pads may project above the principal surface by an amount between 0 μm and preferably 25 μ or even 50 μm.

The object 1A may comprise at the centre a region 40 for any metallisation (contact, antenna, etc.). The object 1B is parallelepipedal and the object 1C comprises a positive-location device 41 in addition to the previous one.

By virtue of the invention, it is possible to arrange electrical/electronic constituents 4 or metallisations of the object before overmoulding so that the external surface of the constituents 4 is at the same (or substantially the same) level as the external surface of the moulding material on the face 3.

The edge of the housings may be slightly inclined in order to assist removal from the mould. For this purpose, the front surface in contact with the support is slightly greater than the opposite rear surface.

By means of the invention it is thus possible to reduce the thickness of these objects to the maximum possible extent. The chip may be placed directly on one of the metallisations or directly on the support. The number of superimposed elements constituting the object is reduced (no supporting film in the final constitution of the object, unlike the prior art).

In another variant concerning the fixing of the chip, the latter may be bonded directly to the low-adhesiveness support, unlike FIG. 3. Thus, after removal of the support, the glue fixing the chip is at the same level as that of the insulating front surface 3 (moulding material) of the housing or substantially at the same level as the metallisations.

In another variant alternative to the above, it is even possible to push the reduction in the thickness of the housing to its maximum by depositing the chip directly on the low-adhesiveness support or a support coated with an adhesive described previously. Thus, after removal of the support, the rear face of the chip is situated on the surface of the housing after removal of the support.

Where applicable, an electronic component such as a fingerprint sensor may be on the surface of the face 3 of the object since it is mounted like the chip 3 on the surface directly against the support (in particular of low adhesiveness).

Where applicable, the two opposite faces of the object are each provided with an overmoulded component/element: the invention may make provision for producing contact pads, other metallisations or other electrical/electronic constituents on a face of the object as described above while another component, such as a fingerprint sensor or the like, is produced on the opposite face while appearing on the external surface of the face. Thus a component such as an electronic chip or element fulfilling a fingerprint sensor function may be mounted so as to offer a flat surface, in particular the fingerprint capture surface, towards the outside.

For the moulding operation, this aforementioned flat surface may come into contact with the top of the cavity EM during the moulding in order to prevent overmoulding on top. Where applicable, it is possible to provide a removable protective film or other protective layer on the fingerprint sensor in order to prevent contamination of the surface during overmoulding.

The moulding may use various methods known to persons skilled in the art carried out hot or cold or by reaction (RIM).

1. A method for producing an electronic housing of a chip card or telecommunication module type, comprising an electronic chip in the housing, a face comprising at least one set of conductive metallisations on the face, said method comprising the following steps:
provision or production of at least one set of metallisations comprising conductive circuit pads and/or tracks, on one side of a support;
transfer and connection of a chip to each set of metallisations,
overmoulding of each chip with its set of metallisations, on the support with a moulding material for producing at least one housing,
separation of the housing from its support;
wherein the side of the support in contact with the metallisations comprises an adhesive or has low adhesiveness, and wherein the overmoulding is carried out at the final dimension of the housing.

2. A method according to claim 1, wherein the overmoulding is carried out so that the external surface of the metallisations is at the same level or substantially at the same level as the external surface of the moulding material on the face.

3. A method according to claim 1, wherein the support is removed from the metallisations or is destroyed or altered with regard to its adhesion, by adding heat.

4. A method according to claim 1, wherein the support is disconnected from the metallisations by adding heat during the overmoulding in a mould, the support carrying the metallisations and at least one connected chip being introduced into a mould.

5. A method according to claim 1, wherein the support has a plurality of housing-reception regions.

6. A method according to claim 1, wherein two opposite faces of the housing are each provided with an overmoulded component on the surface of their respective faces.

7. Moulding equipment for manufacturing an electronic housing comprising an electronic chip, one face of which comprises at least conductive metallisations, according to the method of claim 1, said equipment comprising:
a bottom part for receiving and positioning an adhesive or low-adhesiveness support, comprising at least one set of metallisations comprising conductive-circuit pads or tracks and an attached chip electrically connected to each set of metallisations;
a top part comprising a plurality of moulding compartments configured for overmoulding each chip on its support;
wherein each moulding compartment has the final dimensions or shapes of the housing.

8. Moulding equipment according to claim 7, wherein the equipment is configured to separate the support when the mould is opened, and comprises holding or traction means exerting a separation force on the support when the mould is opened, and ejectors for ejecting the housings from their cavity after opening of the mould.

9. An electronic housing of a chip card or M2M or SIM telecommunication module type, obtained by the method according to claim 1.

10. An electronic housing of a chip card or M2M or SIM telecommunication module type, obtained by the moulding equipment according to claim 7.

11. The method according to claim 6, wherein the overmoulding components on the opposite faces of the housing comprise contact pads on one face and a fingerprint sensor on the opposite face.
